(19) United States
(12) Patent Application Publication
(10) Pub. No.: US 2008/0122351 A1
(43) Pub. Date: May 29, 2008

(54) Organic electroluminescence display and method of manufacturing the same

(75) Inventor: Eiichi Kitazume, Tokyo (JP)

Correspondence Address: SQUIRE, SANDERS & DEMPSEY L.L.P., 1 MARITIME PLAZA, SUITE 300, SAN FRANCISCO, CA, 94111, US

(73) Assignee: Toppan Printing Co., Ltd., Tokyo (JP)

(21) Appl. No.: 11/986,576

(22) Filed: Nov. 21, 2007

(30) Foreign Application Priority Data
Nov. 28, 2006 (JP) 2006-319825

(51) Int. Cl. H01L 51/54; H01L 51/56

(52) U.S. Cl. 313/504; 445/24

(57) ABSTRACT

The present invention provides a top emission type active matrix-drive type organic EL display panel having an electrode of low resistance without degradation of its characteristics and a method of manufacturing the same. Further, the present invention provides an organic EL display panel having an electrode of low resistance without degradation of its characteristics. One embodiment of the present invention is an organic EL display panel, comprising a first electrode, a second electrode, an organic light emitting medium layer between both electrodes, a transparent insulating film formed on a transparent electrode among both electrodes, the film being placed on a light emitting area, and a supporting electrode electrically connected to the transparent electrode being placed on a non-light emitting area.

### CROSS REFERENCE

This application claims priority to Japanese application number 2006-319825, filed on Nov. 28, 2006, which is incorporated by reference.

### BACKGROUND OF THE INVENTION

1. Field of the Invention

The present invention is related to an organic electroluminescence display panel used for an image display panel and an illuminating device, and a method of manufacturing the same. Especially, the present invention is related to an active matrix-drive type organic electroluminescence (EL) display panel which can quickly display an image (rapid-response) using low level power and a method of manufacturing the same.

2. Description of the Related Art

In recent years, an organic EL panel is gathering attention in a climate where demand for a thin and light display device with low power consumption is increasing, according to advanced information society.

The configuration of an organic EL display panel is a simple and basic configuration whereby a light emitting layer including an organic light emitting material was sandwiched between a first electrode and a secondary electrode. When a voltage is applied between these electrodes, the light which occurs when a hole injected by one electrode and electrons injected by the other electrode recombine in a light emitting layer, is used as an image display or a light source.

When putting such an organic EL display panel into practical use, an active matrix drive-type organic EL display panel has been developed in many laboratories in which a substrate with a pixel switch such as TFT is used as a back plane (a back substrate). Organic EL display panels are divided into a bottom emission type and a top emission type depending on the direction of the light that is taken out. In a top emission type display panel where light is taken out from a sealing side, after an organic light emitting layer has been formed on a back plane with a pixel electrode, a transparent conductive film should be layered thereon.

A sputtering method is generally used for layering such a transparent conductive film; however it is known that an ion, an electron and a recoil molecule, which are generated during layering, damage an organic light emitting layer, thereby the characteristics of a manufactured organic EL display panel deteriorate. (For example, see patent document 1) However, it is known that when a thin conductive film is formed to reduce damage, because electric resistance becomes high, the voltages for every pixel due to a voltage drop become different and the burden on a driver circuit increases. In addition, a method is being considered in which a transparent conductive film is formed by sputtering after a thin metal film is formed so that light passes through the film. However, the thin metal film was oxidized or hydroxidized by the remaining oxygen or water in a vacuum chamber, and therefore the characteristics of the EL deteriorated. In addition, in a case where ITO is used as a transparent electrode, oxygen gas is introduced during layering; however at that time, a problem arose whereby the thin metal film was oxidized. Further, even as a method for avoiding damage when sputtering, this method was insufficient depending on the sputtering conditions.

[patent document 1] JP-A-2004-296234

### SUMMARY OF THE INVENTION

The present invention provides a top emission type active matrix-drive type organic EL display panel having an electrode of low resistance without degradation of its characteristics and a method of manufacturing the same. Further, the present invention provides an organic EL display panel having an electrode of low resistance without degradation of its characteristics. In one embodiment of the present invention an organic EL display panel, having a first electrode, a second electrode, an organic light emitting medium layer between both electrodes, a transparent insulating film formed on an outer surface of a transparent electrode among the first electrode or second electrode and placed on a light emitting region, and a supporting electrode electrically connected to the transparent electrode and placed on a non-light emitting region, is proposed.

### BRIEF DESCRIPTION OF THE DRAWINGS

FIG. 1 is an enlarged cross section view of a TFT substrate with a pixel electrode.

FIG. 2 is a cross section view of an organic EL device of an embodiment of the present invention.

FIG. 3 is an enlarged cross section view of an organic EL device of an embodiment of the present invention.

FIG. 4 is an enlarged cross section view of an organic EL device of an embodiment of the present invention.

FIG. 5 is an enlarged cross section view of an organic EL device of an embodiment of the present invention.

FIG. 6 is a schematic diagram of a relief printing machine.

In these drawings, 1 is a support medium; 2 is an active layer; 3 is a gate insulator; 4 is a gate electrode; 5 is an interlayer dielectric; 6 is a drain electrode: 7 is a planarizing layer; 8 is a contact hole; 9 is a scanning wiring; 10 is a source electrode; 11 is an active matrix substrate; 12 is a pixel electrode; 13 is a partition wall; 14a is a hole transport layer; 14b is an organic light emitting layer (an organic electroluminescence layer); 15 is a counter electrode; 16 is a transparent insulating layer; 17 is a supporting electrode; 18 is a transparent conductive film; 19 is a display area (a pixel); 20 is a non-display area; 21 is an ink tank; 22 is an ink chamber; 23 is an anilox roll; 23a is an ink layer; 24 is a printing plate; 25 is a printing cylinder; 26 is a substrate; and 27 is a flat base.

### DESCRIPTION OF THE PREFERRED EMBODIMENTS

An active matrix drive-type organic EL display panel of the present invention comprises a substrate arranged with at least a thin film transistor, a pixel electrode which is formed over a thin film transistor through a planarizing layer, wherein the pixel electrode is connected to the thin film transistor through a contact hole for every pixel, an organic light emitting medium layer formed over the pixel electrode, a transparent counter electrode formed over an organic light emitting medium layer and an insulating layer forming the upper part of the counter electrode but which is not formed on a part of a non-display area. Further, a conductive film is formed on the non-display area. Alternatively, an organic EL display panel may comprise a transparent conductive film formed on the entire surface and a conductive film formed on a non-display area. In addition, depending on the method of forming an organic light emitting medium layer, a partition wall which covers an edge of an electrode and sections each pixel is formed in order to prevent short circuit or color mixture inside a pixel or between adjacent pixels.

In an active matrix drive-type organic EL display panel of the present invention, since a supporting electrode is provided on a counter electrode, even if a counter electrode is thin and resistance thereof is high, an electric current can be sufficiently supplied to each pixel. In addition, an organic light emitting medium layer is formed by supplying an organic light emitting medium ink, such ink generally being a solution and in a dispersed state, to an area sectioned by a partition wall; however, in a case where an organic light emitting medium layer comprises plural layers, a solvent used in an ink for an upper layer must be a poor solvent for a material used in a lower layer. In an active matrix drive-type organic EL display panel of the present invention, since a counter electrode is formed once on an organic light emitting medium layer, a method of forming a support electrode for this upper part can be selected from effective printing methods regardless of the organic light emitting medium material of the lower layer.

### <Substrate>

In the substrate 11 (back plane) used in an active matrix drive-type organic EL display panel, a planarizing layer 7 is formed on a TFT and a lower part electrode (pixel electrode 12) of an organic EL display panel is formed on the planarizing layer 7. A contact hole 8 is installed in the planarizing layer 7 and the lower part electrode is electrically connected to TFT by means of the contact hole 8. Due to such a constitution, a superior electrical insulating property can be achieved between the TFT and an organic EL display panel.

The TFT and an active matrix-drive type organic EL display panel formed above the TFT are supported by a support medium 1. The support medium may preferably be excellent in mechanical strength, insulating property and dimensional stability.

For example, the following materials can be used as a support medium:

1. glass, quartz, plastic film or sheet such as polypropylene, polyether sulfone, polycarbonate, cycloolefin polymers, polyarylate, polyamide, polymethyl methacrylate, polyethylene terephthalate and polyethylenenaphthalate;

2. a transparent substrate on which a plastic film or sheet is laminated by a single layer or plural layers comprised of the following material:

metallic oxide such as oxidation silicon and alumina;

metal fluoride such as aluminium fluoride and magnesium fluoride;

metal nitrides such as silicon nitride and aluminum nitride;

metal acid nitride such as oxynitriding silicon;

macromolecule resin film such as acrylic resin, epoxy resin, silicone oil and polyester resin; and

metallic foil, sheet or board made of aluminium or stainless, and

3. a non-transparent substrate on which a plastic film or sheet is laminated by a metal membrane such as aluminium, copper, nickel and stainless.

The transparency of the substrate may be selected depending on the direction from which light is taken out.

A support medium comprising these materials is necessary in order to avoid entry of moisture to an organic EL display panel. For example, an inorganic film is formed on a support medium. Or fluorocarbon resin is applied to a support medium. It is desirable that exclusion of moisture and hydrophobic processing of a support medium are performed in this way. Particularly it is desirable to lower the moisture content in a support medium and gas transmission coefficient to avoid entry of moisture to an organic light emitting media layer.

A well-known thin film transistor can be used for a thin film transistor on support medium 1. Specifically, a thin film transistor is given as an example comprising the gate insulator and the gate electrode and having the active layer in which a source/drain region and a channel area are formed. The configuration of a thin film transistor is not limited to this configuration. For example, staggered type, reverse staggered type, top gate type, and coplanar type are exemplified.

An active layer 2 can encompass many embodiments. By way of example only, the active layer 2 can be formed by an inorganic semiconductor material such as amorphous Si, polycrystalline silicon, crystallite Si, cadmium selenide or an organic semiconductor material such as thiophene oligomer, and poly (phenylene vinylene).

A manufacturing method of these active layers is exemplified below:

A Method for doping ion after depositing amorphous silicon by a plasma CVD method can comprise the following processes: Formation of amorphous silicon by LPCVD method with the use of SiH₄ gas; ion doping by an ion implantation method after the formation of a polySi by crystallization of amorphous silicon by solid phase epitaxy. A method (low temperature processing) comprising the following processes: Formation of amorphous silicon by LPCVD method with the use of Si₂H₆ gas (or formation of amorphous silicon by PECVD method with the use of SiH₄ gas.); Annealing by laser such as an excimer laser; ion doping by an ion doping method after the formation of a polySi by crystallization of amorphous silicon. A method (high temperature processing) comprising the following processes: Laminating a polySi by low pressure CVD method or LPCVD method; Formation of a gate insulator by thermal oxidation at more than 1,000 degrees Celsius; ion doping by an ion implantation method after formation of a gate electrode 4 of n+ polySi above the gate insulator.

A conventional gate insulator can be used for gate insulator 3. By way of example only, SiO₂ formed by PECVD method or LPCVD method, SiO₂ provided by thermal oxidation of a polysilicon film can be used.

A conventional gate electrode can be used for gate electrode 4, Metal such as aluminum, copper, refractory metal such as titanium, tantalum and tungsten, a polySi, silicide of refractory metal, or polycide can be used.

A thin film transistor 120 can have a single gate structure, a double gate structure, or a multiple gating configuration having three or more gate electrodes. In addition, the thin film transistor 120 can even have an LDD configuration and an offset configuration. Furthermore, two or more thin film transistors may be placed on one pixel.

In some embodiments, it is necessary for a display panel of the present invention to be connected to so that a thin film transistor functions as a switching element of an organic electroluminescent display panel. The drain electrode 6 of a transistor is electrically connected with the pixel electrodes of the organic electroluminescent display panel. In the case of a top emission configuration, it is necessary for metal reflecting back light to be generally used as pixel electrodes.

The connection between the drain electrode 6 of a thin film transistor and the pixel electrodes 12 of the organic electroluminescent display panel is performed by electric wiring formed in the contact hole 8 which passes through planarizing layer 7.

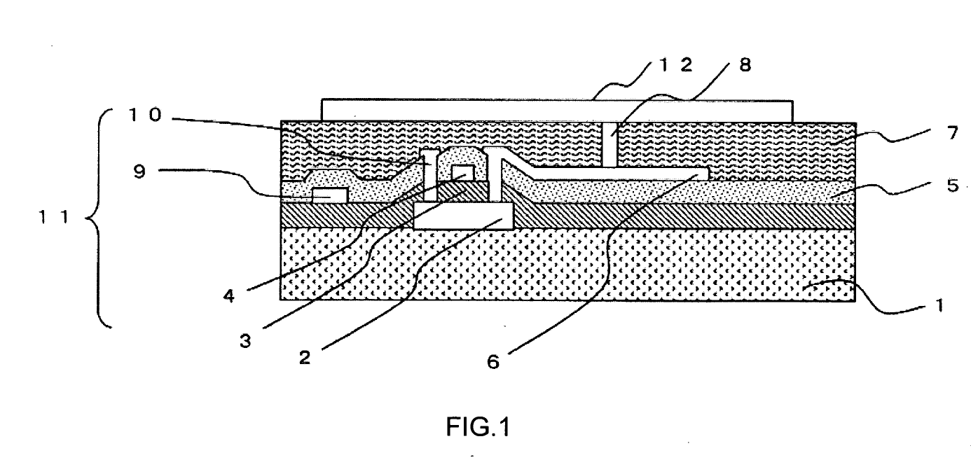

Inorganic materials such as SiO₂, spin-on-glass, SiN (Si₃N₄), TaO (Ta₂O₅), organic materials such as polyimide resin, acrylic resin, photoresist material, and black matrix material can be used as a material for the planarizing layer 7. Spin coating, CVD, and evaporation method can be selected depending on these materials. A photosensitive resin is used as a planarizing layer if necessary, and, the contact hole 8 is formed by a photolithography procedure or after having formed a planarizing layer on the whole area, the contact hole 8 is formed in a position corresponding to the lower layer thin film transistor by dry etching or wet etching. The contact hole is then filled by a conductive material and, the contact hole is connected with pixel electrodes on a planarizing layer. The thickness of the planarizing layer should be sufficient to cover the TFT, capacitor, and electric wiring, for example, several μm, and, by way of example only, it can be about 3 μm. FIG. 1 shows an example of a substrate which can be used as a substrate for an active matrix drive-type organic EL display.

### <Pixel Electrode>

The pixel electrode 12 is layered on the substrate 11. Patterning of the pixel electrode 12 is performed if necessary.

According to the present invention, a pixel electrode is sectioned by the partition wall and corresponds to each pixel. The material of a pixel electrode is described below:

a metal complex oxide such as ITO (indium tin complex oxide), indium zinc complex oxide or zinc aluminium complex oxide; a metallic substances such as gold, platinum and chromium; and the particle dispersion membrane in which finely divided particles of the metallic oxide or the metallic substance are dispersed in epoxy resin or acrylic resin. A single-layered body or a laminated material of the above described material can be used. When a pixel electrode is anode, it is desirable to select a material such as ITO which has a high work function. In the case of so-called bottom emission configuration, it is necessary to select a material with translucency as a pixel electrode material. Metallic substances such as copper or aluminum may be added as a supporting electrode to lower the electric wiring electrical resistance of a pixel electrode if necessary. The following methods can be used for a formation method of a pixel electrode depending on the material: a dry method such as resistance heating evaporation method, an electron-beam evaporation technique, a reactivity evaporation method, an ion plating method and a sputtering method; and a wet method such as the gravure process and screen printing. Depending on the material and the film formation method, existing patterning methods such as a mask evaporation method, photolithography method, wet etching method and dry etching method can be used for a patterning method of a pixel electrode, In a case where a product with TFT is used as a substrate, the product with TFT should be formed so that a pixel electrode is electrically connected to a pixel in a low layer.

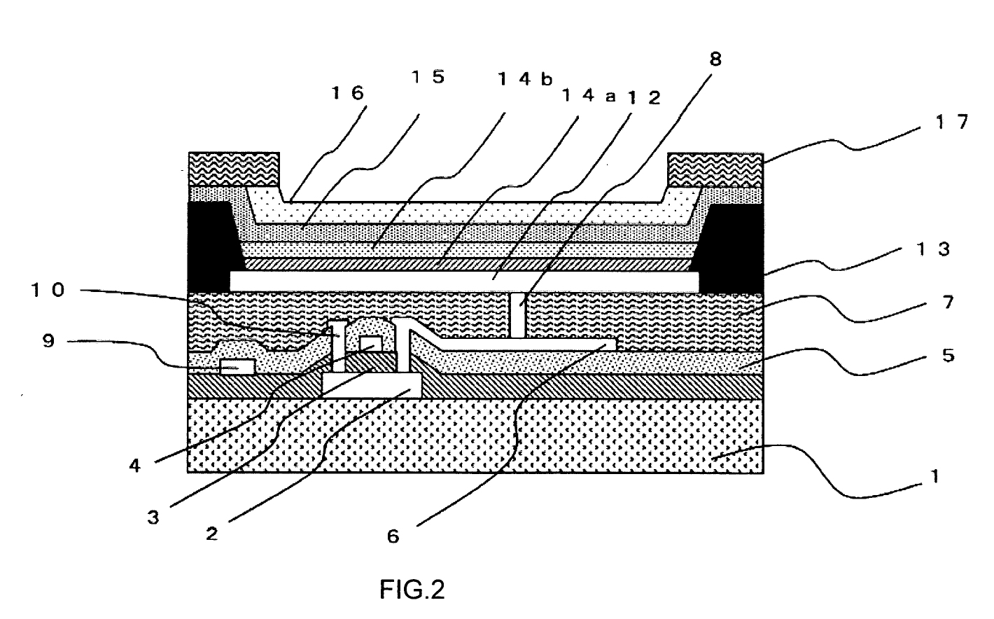

The partition wall 13 of the present invention is formed so as to section a light emitting area corresponding to a pixel. It is desirable that the partition wall is formed so as to cover an edge of the pixel electrode 12. (See FIG. 2) In an active matrix drive-type display panel, the pixel electrode 12 is generally formed for every pixel and the pixel should be as large as possible. Therefore, the most preferable shape of a partition wall to be formed so as to cover an edge of a pixel electrode is basically a grid shape where the partition wall sections each pixel electrode at the shortest distance.

The following conventional method can be used as a formation method of a partition wall:

1. An inorganic film is uniformly formed on a substrate, this substrate is masked with a resist, and dry etching of the inorganic film is performed; or

2. A photosensitive resin is laminated on a substrate, and a predetermined pattern is formed by a photolithography method.

Water-repellent may be added if necessary. The partition wall can be made ink repellent by means of irradiating plasma or UV on the partition wall after the formation of the partition wall,

The height of a partition wall is preferably 0.1 μm-10 μm, more preferably 0.5 μm-2 μm. If a partition wall is too high, it may prevent a counter electrode from forming and prevent sealing. If a partition wall is too low, it can not completely cover an edge of a pixel electrode, or color mixture or short circuit between adjacent pixels occurs when an organic light emitting medium layer is formed.

### <Light Emitting Medium Layer>

After partition wall 13 is formed, the hole transport layer 14a is formed. Examples of hole transport materials which form the hole transport layer 14a include poly aniline derivative, poly thiophenes, polyvinylcarbazole (PVK) derivative and poly (3,4-ethylenedioxy thiophene) (PEDOT). These materials are dissolved or dispersed in a solvent and the hole transport layer 14a is formed by various application methods using a spin coater or the like, or a relief printing method.

After having formed the hole transport layer 14a, an organic light emitting layer 14b is formed. An organic light emitting layer is a layer emitting light by an electric current. Examples of organic luminescent materials forming organic luminescent layers include materials such as a luminous pigment such as coumarin system, perylene system, a pyran system, anthrone system, porphyrin system, quinacridon system, N,N′-dialkyl permutation quinacridon system, naphthalimido system, N,N′-diaryl permutation pyrrolo pyrrole series or iridium complex system. Such a luminous pigment is scattered in macromolecules such as polystyrene, polymethyl methacrylate and polyvinyl carbazole.

In addition, polymer materials such as poly arylene system, PAV [polyarylenevinylene] system or a poly fluorene system can be used.

An organic light emitting material is stably dissolved and/or dispersed by an organic solvent. It can be used as organic luminescent ink.

Solvents such as a toluene, dimethylbenzene, acetone, anisole, methyl ethyl ketone, methyl isobutyl ketone, cyclohexanone or mixture or combination thereof can be used for an organic solvent which can be applied for adjusting an organic light emitting ink.

Preferably, in a point of solubility of an organic light emitting material, an aromatic organic solvent such as toluene, dimethylbenzene, and/or anisole can be used. In addition, detergent, antioxidant, viscosity modifier and UV absorber may be added in an organic light emitting ink if necessary.

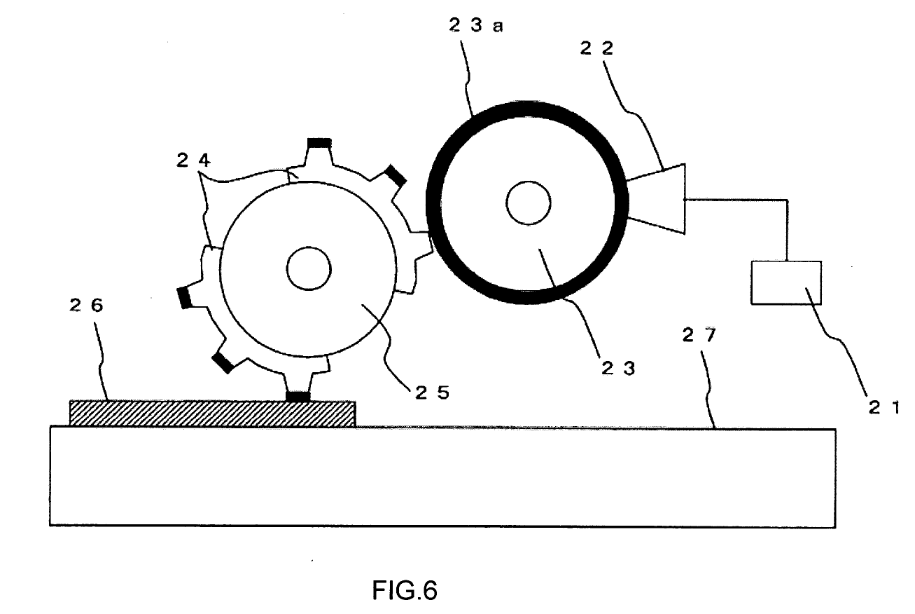

FIG. 6 shows a schematic diagram of a relief printing apparatus which pattern-prints an organic light emitting ink comprising an organic light emitting material on a substrate on which pixel electrodes, an insulator layer and a hole transport layer are formed.

This relief printing device has an ink tank 21, an ink chamber 22, an anilox roll 23 and a plate cylinder 25 on which a plastic relief printing plate 24 is equipped. An organic light emitting ink which is diluted by a solvent is kept in the ink tank 21. An organic light emitting ink is sent into the ink chamber 22 from the ink tank 21. The anilox roll 23 makes contact with an ink feed section of the ink chamber 22, and it is rotatably supported.

According to the rotation of the anilox roll 23, an ink layer 23a comprising an organic light emitting ink supplied on an anilox roll face becomes uniform. The ink of this ink layer is transferred to the projection parts of a plate 24 mounted on a printing cylinder 25 which is rotationally driven in proximity to an anilox roll. A substrate 26 on which transparent electrodes and an insulator layer are formed is transported to a printing position of a flat base 27 by the transporting means that are not illustrated. The ink on the projection parts of the plate 24 is printed on the substrate 26. The ink is dried if necessary. An organic light emitting layer is formed on a substrate in this way.

### <Counter Electrode>

Next, a counter electrode 15 can be formed as illustrated in FIG. 2. When a counter electrode is a cathode, the material discussed below can be used.

The material can be of a type with high electron injection efficiency to an organic light emitting medium layer 14 and low work function.

In some embodiments, the counter electrode 15 can include a metal such as Mg, Al, Yb and combination of the same.

In addition, the following layer stack may be put in a boundary surface of the luminescent medium. The layer stack has a chemical compound of about 1 nm thicknesses such as Li and oxidation Li, LiF and Al and Cu of stability and/or high conductivity. Stability should be balanced with electron injection efficiency. Therefore an alloy system may be used. An alloy of more than one kind of metal such as Li, Mg, Ca, Sr, La, Ce, Er, Eu, Sc, Y, and Yb that has a low work function, and a metallic element such as Ag, Al, and Cu which is stable can be used. In some embodiments, an alloy such as MgAg, AlLi, and CuLi can be used.

Depending on the material, a resistance heating evaporation coating method, an electron beam-evaporation coating method, a reactive deposition method, an ion plating method, or a sputtering method can be used for the method of forming the counter electrode 15. Since it is necessary for a counter electrode to be a transparent electrode layer, it is desirable that a counter electrode be thin in order to be transparent. Therefore, in a case where a metallic material such as Ca, Ba or Li is used for a material of a counter electrode, a film thickness of a counter electrode is preferably equal to or less than 30 nm, most preferably equal to or less than 20 nm.

It is desirable that a film thickness of a counter electrode be equal to or more than 10 nm to secure ohmic value as an electrode and also to maintain configuration as a film.

### <Transparent Insulating Layer>

A transparent insulating layer 16 to be formed on the transparent counter electrode 15 is arranged in an active matrix-drive type organic electroluminescence display panel of the present invention. The transparent insulating layer 16 is a film which can be layered by evaporation. Examples of transparent insulating layers include oxide such as SiO₂, SiO, GeO and MoO₃, fluoride such as MgF₂, LiF, BaF₂, AlF₃ and FeF₃, and inorganic compounds such as GeS and SnS. It is desirable that a film thickness of these films be adjusted in order to achieve transmittance of 50% or more.

### <Supporting Electrode>

A supporting electrode 17 is arranged in an active matrix-drive type EL display panel of the present invention. The supporting electrode 17 is formed on non-pixel area, therefore there is no obstruction to the display performance of the display panel. Further, the supporting electrode 17 can repair or support a counter electrode cut by an edge of partition wall. Any conductive film can be used for a material of a supporting electrode, however a metal film is preferable.

In addition, further, a supporting electrode may cover an edge of a transparent insulating layer. (See FIG. 2) In a case where a supporting electrode covers an edge of a transparent insulating layer, sealing can be improved.

### <Transparent Conductive Film>

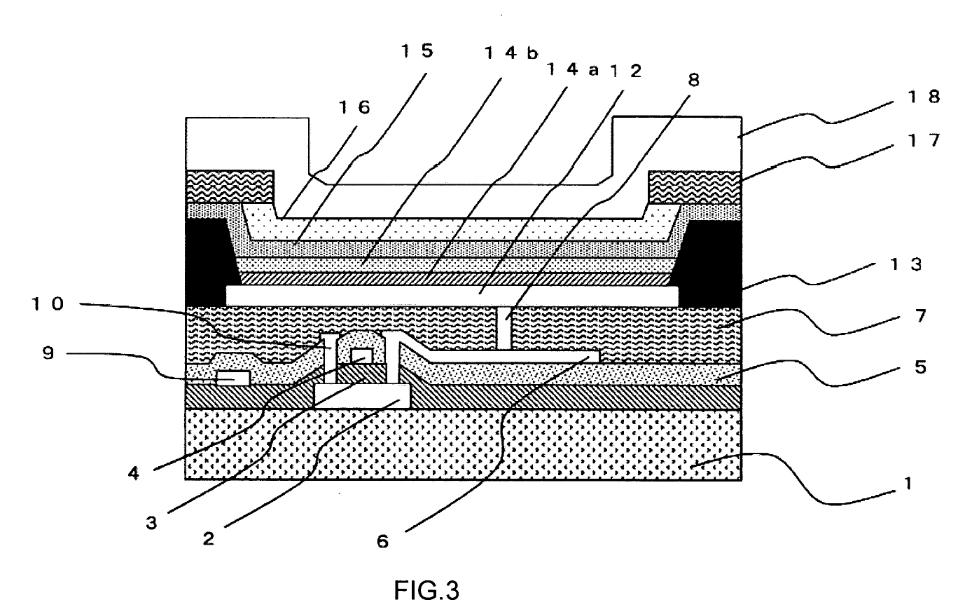

Examples of a transparent conductive film 18 which is arranged in an active matrix-drive type organic EL display panel of the present invention, include a metal complex oxide such as ITO (indium-tin complex oxide), indium-zinc complex oxide or zinc-aluminum complex oxide. (See FIG. 3)

### <Sealing Body>

As an organic electroluminescent display panel, a light emitting material is sandwiched between electrodes, and light can be emitted by applying an electric current, however, organic light emitting material easily deteriorates by means of atmospheric moisture and oxygen. Thus a seal to seclude the organic light emitting layer and the like from the outside is usually provided.

For example, a sealing body can be manufactured by providing a resin layer on a sealing medium.

For a sealing medium, it is necessary for the permeability of moisture and oxygen to be low.

In addition, ceramics such as alumina, silicon nitride and boron nitride, glass such as no-alkali glass, alkali glass, quartz, humidity resistance film are given as examples of a material for a sealing medium.

By way of example only, the following humidity resistance film is exemplified: a film which forms SiOx by a CVD method on both sides of a plastic substrate; a film with low permeability laminated by an absorbent film or a polymer film which is applied with a water absorption agent. It is preferable for the water vapor permeation rate of the humidity resistance film to be less than 10⁻⁶ g/m²/day.

For example, the following materials can be used for a resin layer:

A photo-curing adhesive property resin, a heat curing adhesive property resin and 2 fluid hardening adhesive property resin comprising an epoxy type resin, acrylic resin, silicone oil and the like, acrylic resin such as ethylene ethylacrylate (EEA) polymer, vinyl resins such as ethylene vinyl acetate (EVA), thermoplastic resin such as polyamide, a synthetic rubber, thermoplasticity adhesive property resins such as acid denatured substances of polyethylen or polypropylene. An example of a method to form a resin layer on a sealing medium is shown below: solvent solution method, pushing out laminate method, fusion/hot melt method, calender method, discharge jet application method, screen printing, vacuum laminate method and heated roll laminate method. A material having hygroscopicity and a property to absorb oxygen can be incorporated into adhesive if necessary. Depending on the size and configuration of a sealed organic electroluminescent display unit, the thickness of a resin layer installed in a sealing medium is fixed. About 5-500 μm is desirable for the thickness of a resin layer. In addition, in the above described example, a resin layer may be formed on a sealing medium. However, a resin layer can be directly formed on an organic EL side.

Lastly, an organic EL display panel is affixed to a sealing body in a sealing room.

In the case when the sealing body has a two layer construction consisting of a sealing medium and a resin layer using a thermoplastic resin for the resin layer, contact bonding should be performed only by a heating roller.

When a heat curing type adhesive resin is used as the sealing body, after attaching by pressure from a heating roller a heat curing type adhesive resin is heated and hardened.

In the case of a photo-curing-related adhesive resin, the sealing body is sealed by pressure from a roller and a photo-curing-related adhesive resin is hardened by irradiating a light.

Before sealing using a sealing body or instead of sealing using a sealing body, sealing by an inorganic thin film may be performed. For example, sealing is possible by forming a silicon-nitride film as a passivation film, to a thickness of 150 nm using a CVD method.

An active matrix-drive type organic EL display panel is described as above. However, the present invention is suitable for a passive matrix-drive type organic EL display panel in which a first electrode, a second electrode which are separated by an organic light emitting medium layer, are intersecting each other as an anode line and a cathode line respectively (In an active matrix-drive type organic EL display panel, the transparent electrode among a first electrode and a second electrode is a counter electrode, and a non-transparent electrode among a first electrode and a second electrode is a pixel electrode).

In the case of a passive matrix-drive type organic EL display panel, a transparent conductive film is not formed on the entire surface of a light emitting area and a non-light emitting area. That is, the transparent conductive film is electrically connected in a non-light emitting area of a transparent line electrode and is placed to cover a transparent insulating film in a light emitting area; however an area without a transparent conductive film is provided in a space between transparent line electrodes, thereby transparent line electrodes should not be connected electrically to each other.

Herein, a non-light emitting area in the present invention means a non-light emitting area near a pixel such as a space between pixels, but does not means an area where an adhesive is applied for sealing and an area where a driver chip is packaged.

In an active matrix-drive type organic EL display panel of an embodiment of the present invention, a thin film of alkali metal or alkaline earth metals, having a low work function, is used as a transparent counter electrode, and transparent insulating film is formed on a light emitting area of a transparent counter electrode. In this embodiment, a transparent insulating film is formed in an area without a non-light emitting area such as a space between pixels. Thereafter, a conductive metal film is formed in an area without an insulating layer. The conductive metal film plays a role of a supporting electrode. Further, since an insulating layer is formed on a counter electrode in a display area, degradation of a film can be controlled where the degradation of a film is caused by remaining water or oxygen in a vacuum chamber during forming of a supporting electrode or during transport of a substrate.

In an active matrix-drive type organic EL display panel of another embodiment of the present invention, a thin film of alkali metal or alkaline earth metals, having a low work function, is used as a transparent counter electrode, and transparent insulating film is formed on a light emitting area of a transparent counter electrode. In this embodiment, a transparent insulating film is formed in an area without a non-light emitting area such as a space between pixels, thereby the above-mentioned effect is achieved. Thereafter, a transparent material, for example ITO, is formed on the entire area comprising a light emitting area and a non-light emitting area. In this embodiment, an organic EL display which is not damaged can be realized by a preformed insulating layer which blocks an ion, an electron and a recoil molecule which are generated during layering at sputtering which is a formation method of a transparent conductive material. In addition, an organic EL display is not influenced by an oxygen gas which is introduced during sputtering, therefore the characteristics of an organic EL display do not deteriorate.

Further, an organic EL display having a counter electrode in which the wiring resistance is lowered, can be realized, wherein a metal is formed in a non-light emitting area as a supporting electrode of another embodiment.

### EXAMPLE 1

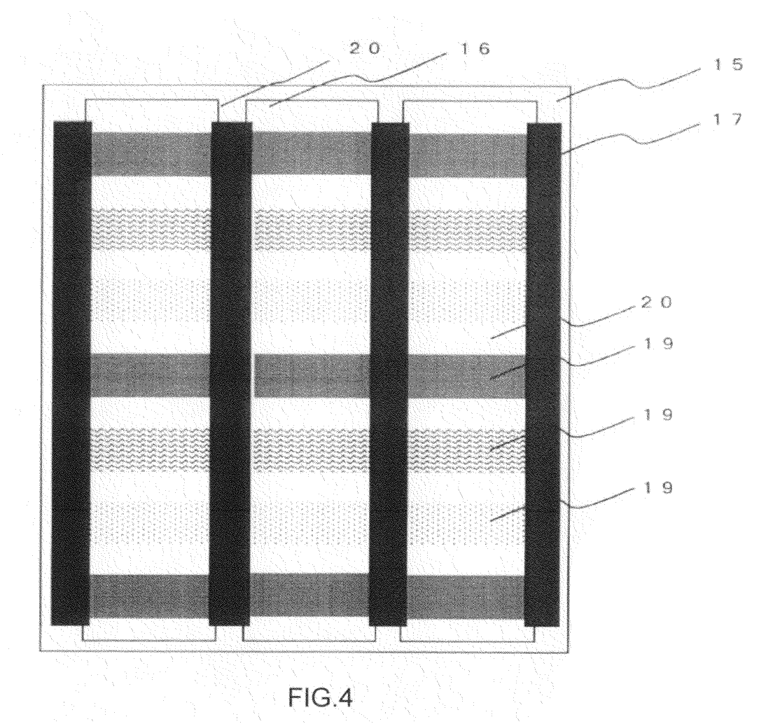

Hereinafter, an example of the present invention is described using FIG. 4.

A top emission type active matrix substrate 11 was used as a substrate which comprised a thin film transistor, provided on a support medium, which functioned as a switching element, a planarizing layer formed over the thin film transistor, and a pixel electrode, provided on the planarizing layer and which was electrically connected to the thin film transistor through a contact hole. The substrate's diagonal size was 5 inches and the number of pixels was 320*240. An active matrix substrate is described below in detail. An active matrix substrate had a support medium, a plurality of signal wires and a plurality of scanning wires 9 where both wirings intersected each other and were formed over the support medium, a plurality of thin film transistors which operated in accordance with a signal applied to the scanning wires, and a plurality of pixel electrodes 19 electrically connected to the signal wires through the thin film transistor. An active matrix substrate may have an interlayer dielectric 5 and a source electrode 10. FIG. 4 shows a display area 19 and a non-display area 20.

A partition wall was formed so that it covered an edge of a pixel electrode formed on this substrate and sectioned a pixel. The formation method of the partition wall comprised: applying a positive resist (ZWD6216-6, a product of ZEON Corporation), at a thickness of 2 μm, by a spin coater and forming the partition wall to a width of 40 μm by photolithography. In this way, a pixel area was sectioned, wherein the number of sub pixels was 960*240 and a pitch was 0.12*0.36.

A mixture (PEDOT/PSS) of poly (3,4-ethylenedioxy thiophen) and polystyrene sulfonate of 0.1 μm thickness as a hole transport layer was formed on a pixel electrode by a spin coat method. Thereafter, unnecessary parts were wiped off using methanol.

After this substrate had been set on a printing machine, an organic light emitting layer was printed by a relief printing method on a pixel electrode between insulating layers by using an organic light emitting ink which was dissolved in toluene so that the concentration of a polyphenylene vinylene derivative, which is the organic light emitting material, was 1%. In this case, an anilox roll of 150 lines/inch and a photosensitive resin printing plate which was developable by water were used. The film thickness of an organic light emitting layer after printing and drying was 80 nm. In this way, an organic light emitting medium layer comprising a hole transport layer and an organic light emitting layer was formed.

A Ca film 15 of 20 nm thickness was layered as a counter electrode on the entire surface by a vacuum evaporation method. Thereafter, a mask which had a lateral stripe aperture of 320 μm width was used and position adjustment was performed so that the aperture of the mask corresponded to a pixel area of an organic EL display panel, thereafter a protective insulating layer 16 was formed by layering ZnS of 200 nm thickness by the electron beam evaporation method. Further, a longitudinal metal mask with an aperture of 40 μm was used and position adjustment was performed so that the aperture of the mask corresponded to a non-display area, thereafter a supporting electrode was formed by layering Al of 300 nm thickness.

After a thermal adhesive had been applied to the entire surface of a substrate with a supporting electrode, a glass plate was put on the substrate as a transparent sealing medium so as to cover all light emitting areas, thereafter sealing was performed by curing an adhesive by heat at about 90° C. for 1 hr. As for a panel manufactured in this way, because Ca, which was a counter electrode, was a thin film, light from an organic EL layer passed smoothly through the counter electrode and therefore the emitted light from a sealing side could be taken out. When an active matrix-drive type organic EL display panel obtained in this way was driven, unevenness in luminance, due to a wiring resistance of a counter electrode, did not appear and the state of emitted light was even.

### EXAMPLE 2

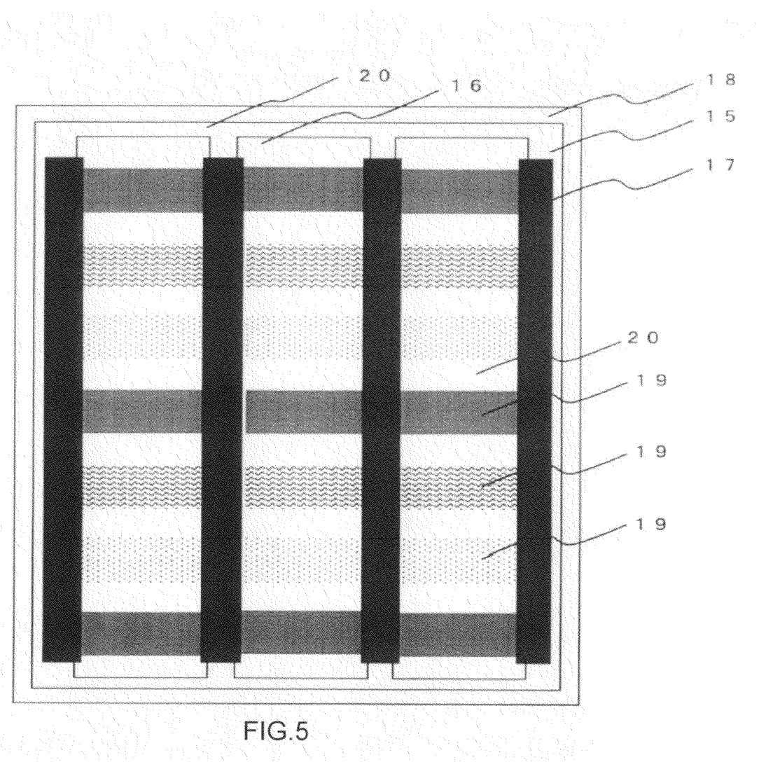

The same steps as in Example 1 were performed up to forming of an organic light emitting medium layer. (See FIG. 5)

Ba film 15 of 20 nm thickness was layered as a counter electrode, on the entire surface by the vacuum evaporation method. Thereafter, a mask which had a lateral stripe aperture of 320 μm width was used and position adjustment was performed so that the aperture of the mask corresponded to a pixel area of an organic EL display panel, thereafter a protective insulating layer 16 was formed by layering yttrium oxide of 200 nm thickness by the electron beam evaporation method. Further, a longitudinal metal mask with an aperture of 40 μm was used and position adjustment was performed so that the aperture of the mask corresponded to a non-display area, thereafter a supporting electrode was formed by layering Al of 300 nm thickness. Further, this substrate was transported to a sputtering apparatus in vacuum condition and was set in a sputtering apparatus. ITO film of 300 nm was layered on the entire surface by magnetron sputtering. In this case, the conditions were as follows: power 1 kW; argon flow rate/oxygen flow rate is 150/1.5 sccm; and 1 Pa.

Similar to Example 1, after a thermal adhesive had been applied to the entire surface of a substrate with a supporting electrode, a glass plate as a transparent sealing medium was put on the substrate so as to cover all light emitting areas, thereafter sealing was performed by curing an adhesive by heat at about 90° C. for 1 hr. As for a panel manufactured in this way, because Ba, which was a counter electrode, was a thin film, light from an organic EL layer passed smoothly through the counter electrode and therefore the emitted light from a sealing side could be taken out. When an active matrix-drive type organic EL display panel obtained in this way was driven, unevenness in luminance, due to a wiring resistance of a counter electrode, did not appear and the state of emitted light was even. Since an insulating protective layer was formed, there was no influence to the display caused by damage at the time of sputtering.

What is claimed is:

1. An organic electroluminescence display panel, comprising:
a first electrode;
a second electrode;
an organic light emitting medium layer between said first electrode and said second electrode;
a transparent insulating layer formed on an outer surface of a transparent electrode which is one of said first electrode and said second electrode, said transparent insulating layer being placed on a light emitting area; and
a supporting electrode electrically connected to said transparent electrode, said supporting electrode being placed on a non-light emitting area.

2. An organic electroluminescence display panel, comprising:
a first electrode;
a second electrode;
an organic light emitting medium layer between said first electrode and said second electrode;
a transparent insulating layer formed on an outer surface of a transparent electrode which is one of said first electrode and said second electrode, said transparent insulating layer being placed on a light emitting area; and
a transparent conductive film electrically connected to said transparent electrode in a non-light emitting area, said transparent conductive film being placed so as to cover said transparent insulating layer.

3. The organic electroluminescence display panel according to claim 2, comprising:
a supporting electrode placed on the non light-emitting area, said supporting electrode being located between said transparent electrode and said transparent conductive film, said supporting electrode being electrically connected to said transparent electrode and said transparent conductive film.

4. An organic electroluminescence display panel, comprising:
an active matrix substrate including a plurality of thin film transistors and a plurality of pixel electrodes;
an organic light emitting medium layer over said active matrix substrate;
a counter electrode over said organic light emitting medium layer;
a transparent insulating film on a light emitting area of said counter electrode; and
a supporting electrode at a non-light emitting area, said supporting electrode being electrically connected to said counter electrode.

5. An organic electroluminescence display panel, comprising:
an active matrix substrate including a plurality of thin film transistors and a plurality of pixel electrodes;
an organic light emitting medium layer over said active matrix substrate;
a counter electrode over said organic light emitting medium layer;
a transparent insulating film on a light emitting area of said counter electrode; and
a transparent conductive film on both a light emitting area and a non-light emitting area, said transparent conductive film being electrically connected to said counter electrode.

6. The organic electroluminescence display according to claim 5, further comprising:
a support electrode between said counter electrode and said transparent conductive film, said support electrode being placed on the non-light emitting area, said support electrode being electrically connected to said counter electrode and said transparent conductive film.

7. A method of manufacturing an organic electroluminescence display panel according to claim 1, wherein
a light emitting layer included in the organic light emitting medium layer is formed by a relief printing method.
